(19) United States
(12) Patent Application Publication
(10) Pub. No.: US 2008/0122505 A1
(43) Pub. Date: May 29, 2008

(54) Charge-pump circuit capable of regulating voltage without any external voltage regulator

(75) Inventor: Chi-Hao Wu, Taipei City (TW)

Correspondence Address: BIRCH STEWART KOLASCH & BIRCH, PO BOX 747, FALLS CHURCH, VA, 22040-0747, US

(73) Assignee: Sitronix Technology Corp.

(21) Appl. No.: 11/514,263

(22) Filed: Sep. 1, 2006

(51) Int. Cl. H03L 7/06

(52) U.S. Cl. 327/157

(57) ABSTRACT

The present invention discloses a charge-pump circuit capable of regulating voltage without any external voltage regulator, wherein an input-modifying circuit is installed between the voltage-input end and the charge-pump circuit and used to detect the variation of the output voltage of the charge-pump circuit and modify the voltage input to the charge-pump circuit via a negative feedback mechanism, and the output voltage is thus regulated and stabilized. Therefore, in the present invention, the input voltage does not change with the variation of loads, and the output voltage is not determined by the input voltage but by the input-modifying circuit.

### FIELD OF THE INVENTION

The present invention relates to a charge-pump circuit, particularly to a charge-pump circuit capable of regulating voltage without any external voltage regulator.

### BACKGROUND OF THE INVENTION

In a common TFT-LCD (Thin Film Transistor Liquid Crystal Display), the voltage input by the driver IC is not high but only within 2.6 to 3.3V However, the LCD panel needs a higher voltage (about 4.5V) to drive. Therefore, a charge-pump circuit is used to raise voltage. The charge-pump circuit is to double the input voltage. When the input voltage is within 2.6 to 3.3V, the charge-pump circuit will boost it to be 5.2 to 6.6V. When other analog circuits need to output higher voltages, the designer has to adopt the widely varying voltage as the terminal voltage. However, the characteristics of the overall circuit are hard to grasp. Then, the design task becomes more difficult. Besides, the circuits need a larger area to prevent the damage caused by high voltage.

Refer to FIG. 1 a diagram schematically showing a conventional charge-pump circuit. The common 2× charge-pump circuit 11 is coupled to a pump capacitor Cp externally, and the output end of the charge-pump circuit 11 is coupled to a grounded output capacitor Co usually having a capacitance of 1 uF. The currently better solution to the abovementioned post-voltage doubling problems is to add an LDO 12 (Low Drop-Out Linear Regulator) to behind the output voltage of the charge-pump circuit 11; thus, the output voltage will not change with the variation of the loads or the input voltage but will be regulated and stabilized to be at a specified voltage (such as 4.8V). Besides, an externally added capacitor Ca (with the same capacitance of Co 1 uF) is added to behind the LDO 12 to accelerate the response to the current or the loads.

The working principle of the LDO 12 is as follows: when the input voltage is greater than the output voltage, the voltage drop thereof is absorbed by transistors and is fed back to a feedback control circuit to stabilize the output voltage. To obtain an output voltage, which is higher than the input voltage and will not change with the variation of the loads or the input voltage, the charge-pump circuit 11 doubles the input voltage, and then, the doubled voltage is processed by the LDO 12 to obtain a regulated output voltage. The regulated output voltage is stable and does not change with the variation of the loads or the input voltage. Such a technology needs an externally added capacitor Ca commonly having a capacitance of 1 uF. However, in many cases, such a capacitor cannot be added externally. Besides, the designers do not usually design such a capacitor in the circuit.

### SUMMARY OF THE INVENTION

The objective of the present invention is to provide a charge-pump circuit capable of regulating voltage without any external voltage regulator to overcome the abovementioned problems, wherein an input-modifying circuit is installed between the input voltage and a charge-pump circuit to modify the voltage input to the charge-pump circuit; when the load is greater, the input-modifying circuit releases more voltage; when the load is smaller, the input-modifying circuit releases less voltage; thereby, the present invention can regulate the output voltage of the charge-pump circuit without adding extra LDO (Low Drop-Out Linear Regulator) and any external capacitor to behind the charge-pump circuit.

To achieve the abovementioned objective, the charge-pump circuit of the present invention is externally coupled to a pump capacitor, and the output end of the charge-pump circuit is coupled to a grounded output capacitor; an input-modifying circuit is installed between the voltage-input end and the charge-pump circuit and used to detect the variation of the output voltage of the charge-pump circuit and modify the voltage input to the charge-pump circuit via a negative feedback mechanism, and the output voltage is thus regulated and stabilized.

The input-modifying circuit further comprises: a modifying transistor, a first resistor, a second resistor, and an error amplifying and comparing element. The modifying transistor is installed between the voltage-input end and the charge-pump circuit. The first resistor and the second resistor are interconnected in series from the output end of the charge-pump circuit; the resistance ratio of the first resistor and the second resistor is n:1, and n is greater than 1; and a partial voltage equal to (1/n) the output voltage is generated in the junction between the first resistor and the second resistor. One input end of the error amplifying and comparing element is coupled to a reference voltage; the other input end is coupled to the junction between the first resistor and the second resistor to obtain the partial voltage of the output voltage at the junction and implement the negative feedback mechanism. The output end of the error amplifying and comparing element is coupled to the control end of the modifying transistor to control the amount of the voltage released by the modifying transistor. Therefore, in the present invention, the input voltage does not change with the variation of loads, and the output voltage is not determined by the input voltage but by the input-modifying circuit.

### BRIEF DESCRIPTION OF THE DRAWINGS

FIG. 1 is a diagram schematically showing a conventional charge-pump circuit.

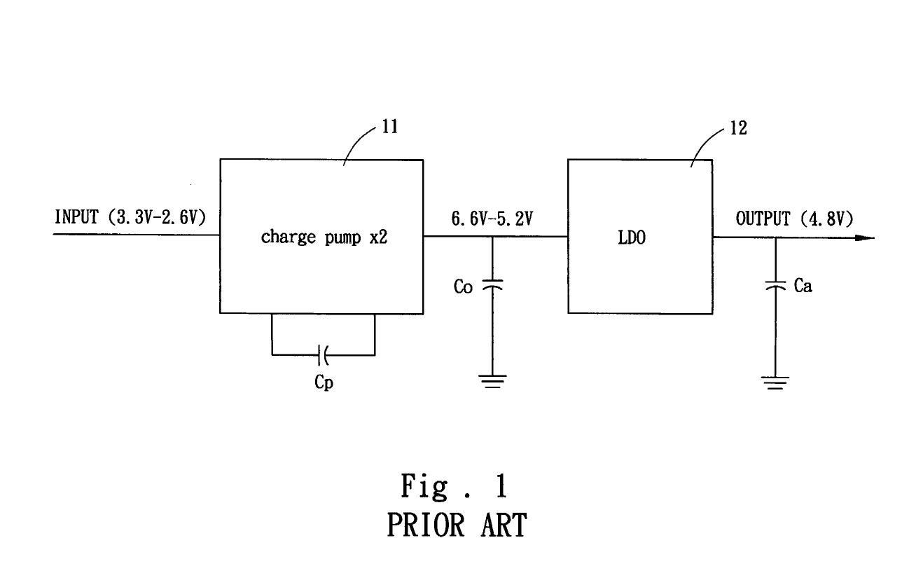

FIG. 2 is a diagram schematically showing the charge-pump circuit according to the present invention.

FIG. 3 is a diagram schematically showing the connection of the charge-pump circuit according to one embodiment of the present invention.

FIG. 4 is a diagram schematically showing the detail of the circuit shown in FIG. 3.

FIG. 5 is a diagram schematically showing the connection of the charge-pump circuit according to another embodiment of the present invention.

FIG. 6 is a diagram schematically showing the detail of the circuit shown in FIG. 5.

### DETAILED DESCRIPTION OF THE PREFERRED EMBODIMENTS

The technical contents of the present invention are to be described in detail in cooperation with the drawings below.

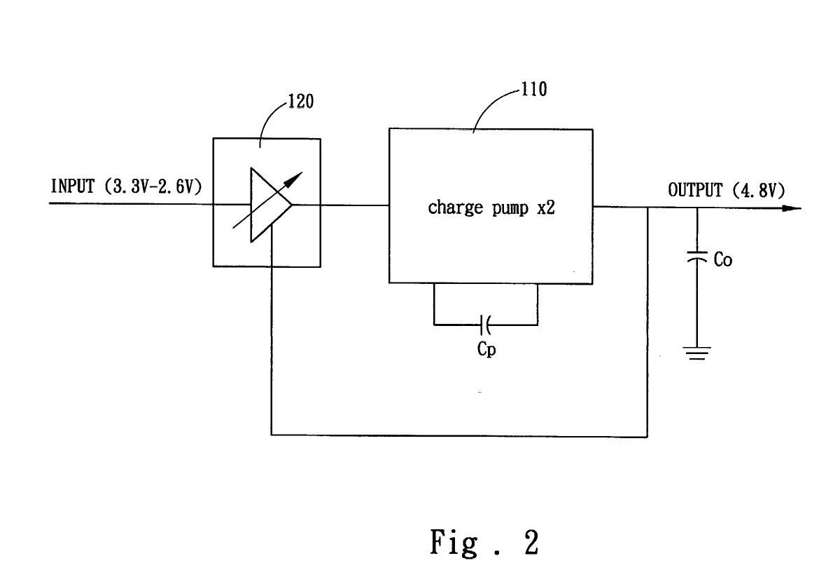

Refer to FIG. 2 a diagram schematically showing the charge-pump circuit according to the present invention. As shown in FIG. 2, the charge-pump circuit 110 of the present invention is externally coupled to a pump capacitor Cp, and the output end (OUTPUT) of the charge-pump circuit 110 is coupled to a grounded output capacitor Co. An input-modifying circuit 120 is installed between the voltage-input end (INPUT) and the charge-pump circuit 110 and used to detect the variation of the output voltage Vout of the charge-pump circuit 110 and modify the voltage input to the charge-pump circuit 110 via a negative feedback mechanism, and the output voltage Vout is thus regulated and stabilized.

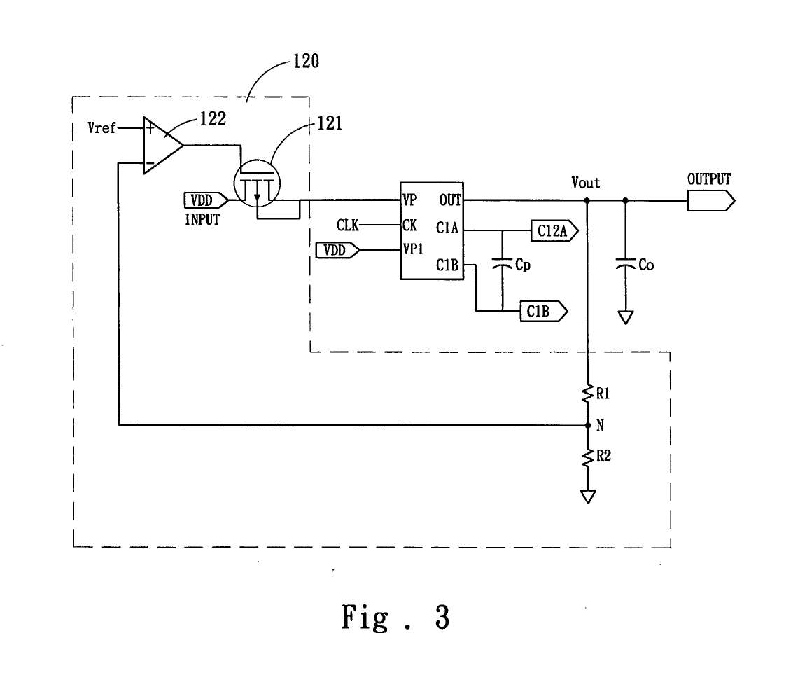

Refer to FIG. 3 a diagram schematically showing the connection of the charge-pump circuit according to one embodiment of the present invention. The input-modifying circuit 120 further comprises: a modifying transistor 121, a first resistor R1, a second resistor R2, and an error amplifying and comparing element 122. The modifying transistor 121 is installed between the voltage-input end (INPUT) and the charge-pump circuit 110. The first resistor R1 and the second resistor R2 are interconnected in series from the output end of the charge-pump circuit 110; the resistance ratio of R1 and R2 is n:1, and n is greater than 1; and a partial voltage equal to (1/n) the output voltage Vout is generated in the junction N between R1 and R2. One input end of the error amplifying and comparing element 122 is coupled to a reference voltage Vref; the other input end is coupled to the junction N between the first resistor R1 and the second resistor R2 to obtain the partial voltage of the output voltage Vout at the junction N and implement the negative feedback mechanism. The output end of the error amplifying and comparing element 122 is coupled to the control end of the modifying transistor 121 to control the amount of the voltage released by the modifying transistor 121. The input-modifying circuit 120 functions like a faucet. When the load is very low, the input-modifying circuit 120 will detect the case and release a smaller amount of voltage. When the load is very high, the input-modifying circuit 120 will detect the case and release a greater amount of voltage. Thereby, the output voltage Vout is regulated and stabilized and is equal to Vout=(1+n)×Vref.

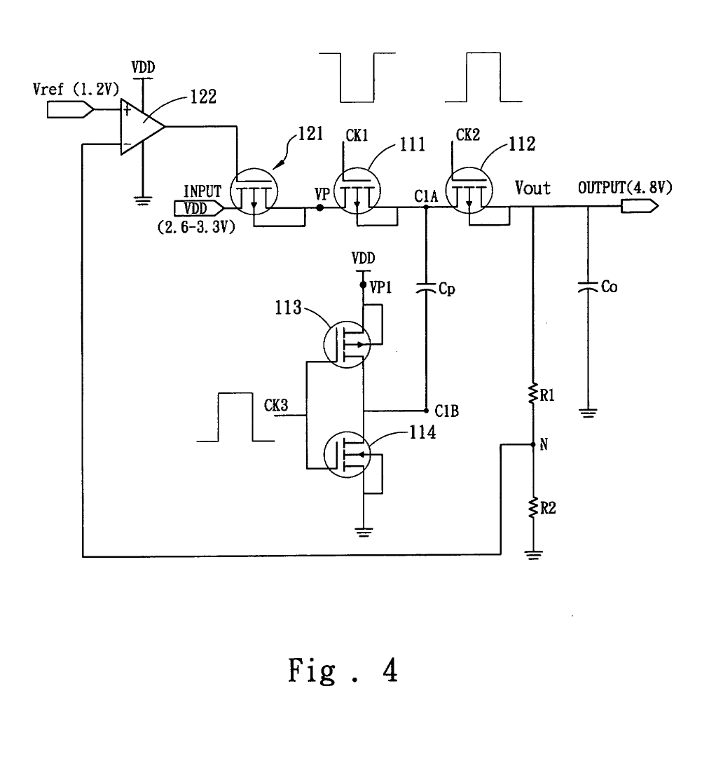

Refer to FIG. 4 a diagram schematically showing the detail of the circuit shown in FIG. 3. A 2× charge-pump circuit is used to exemplify the charge-pump circuit 110. The charge-pump circuit 110 further comprises: a charge transistor 111, a discharge transistor 112, and a phase inverter. The charge transistor 111 and the discharge transistor 112 are sequentially arranged between the input end VP and the output end (OUTPUT) and respectively controlled by a first clock CK1 and a second clock CK2, wherein the first clock CK1 and the second clock CK2 are out of phase. The phase inverter includes: a P-type transistor 113 and an N-type transistor 114; the third clock CK3 of the phase inverter is synchronic with the second clock CK2, and the input end VP1 of the phase inverter is coupled to the source voltage VDD (VDD is commonly within 2.6 to 3.3V). The pump capacitor Cp is installed between the output end C1B of the phase inverter and the junction C1A of the charge transistor 111 and the discharge transistor 112.

As shown in FIG. 4, the modifying transistor 121 is installed between the voltage-input end (INPUT) and the input end VP of the charge transistor 111 of the charge-pump circuit 110. The voltage of the voltage-input end (INPUT) is equal to the source voltage VDD and commonly within 2.6 to 3.3V. When the resistance ratio of the first resistor R1 and the second resistor R2 is 3:1 (For example, the resistance of the first resistor R1 is 300Ω, and the resistance of the second resistor R2 is 100Ω), a partial voltage of one-fourth Vout (Vout/4) is created and sent to the error amplifying and comparing element 122.

When the first clock CK1 of the charge transistor 111 is at the high level, the third clock CK3 is at the low level, and the phase inverter charges the pump capacitor Cp to the source voltage VDD via the P-type transistor 113. When the first clock CK1 of the charge transistor 111 is at the low level, the second clock CK2 and the third clock CK3 are at the high level, and the error amplifying and comparing element 122 modifies the output voltage Vout according to the feedback partial voltage created by the resistors R1 and R2. When the reference voltage Vref at the positive end of the error amplifying and comparing element 122 is 1.2V, and when the resistors R1 and R2 create and send the partial voltage of (Vout/4) to the negative end of the error amplifying and comparing element 122, the error amplifying and comparing element 122 will control the modifying transistor 121 and determine the amount of the voltage released by the modifying transistor 121, and the pump capacitor Cp having been at the source voltage VDD is charged via the charge transistor 111. When there is a load existing, the feedback voltage decreases; once the error amplifying and comparing element 122 detects the case, it controls the modifying transistor 121 to release a greater amount of voltage and regulate the feedback voltage to be at the reference voltage Vref (1.2V) stably; thus, the output voltage Vout is stabilized to be at (1+n) Vref, i.e. Vout=(1+n)×Vref=(1+3)×1.2 V=4.8V.

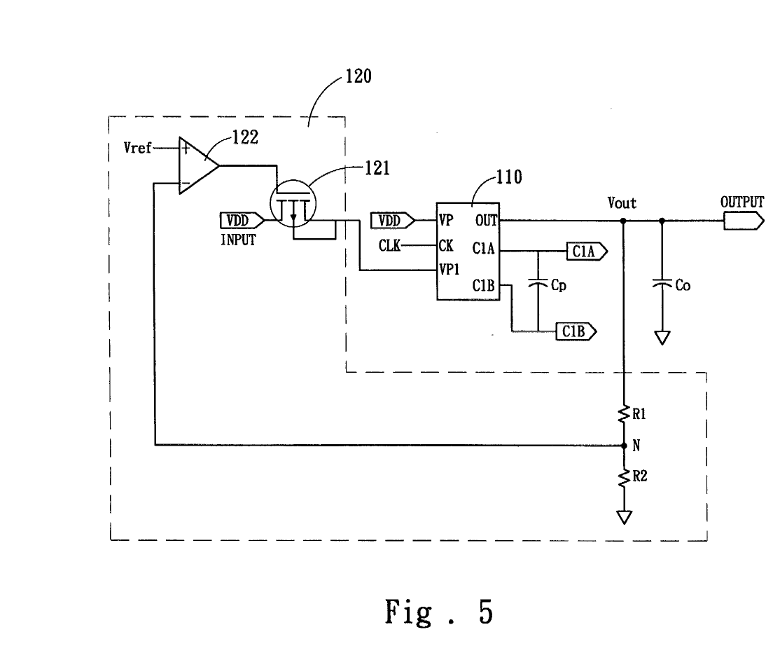

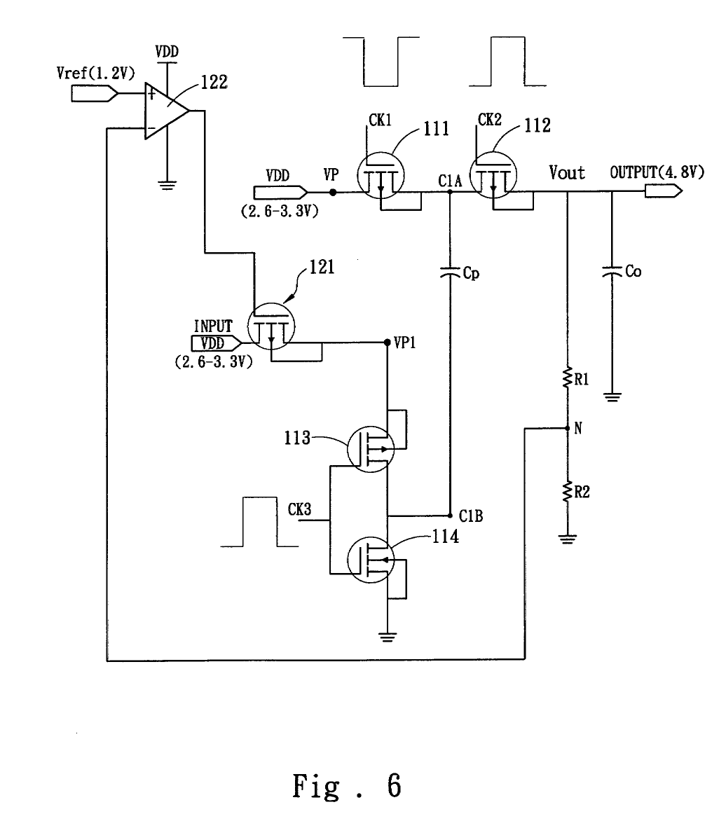

Refer to FIG. 5 a diagram schematically showing the connection of the charge-pump circuit according to another embodiment of the present invention, and refer to FIG. 6 a diagram schematically showing the detail of the circuit shown in FIG. 5. A 2× charge-pump circuit is also used to exemplify the charge-pump circuit 11 herein, and the infrastructure thereof is similar to that mentioned above. However, the modifying transistor 121 is coupled to the input end VP1 of the phase inverter, and the input end VP of the charge transistor 111 is coupled to the source voltage VDD.

Similarly, the voltage of the voltage-input end (INPUT) is equal to the source voltage VDD, and suppose the resistance ratio of the first resistor R1 and the second resistor R2 is 3:1 (For example, the resistance of the first resistor R1 is 300Ω, and the resistance of the second resistor R2 is 100Ω), and a partial voltage of ¼ Vout is created and output to the error amplifying and comparing element 122.

When the first clock CK1 of the charge transistor 111 is at the high level, the third clock CK3 is at the low level, and the error amplifying and comparing element 122 modifies the output voltage Vout according to the feedback partial voltage created by the resistors R1 and R2. When the reference voltage Vref at the positive end of the error amplifying and comparing element 122 is 1.2V, and when the resistors R1 and R2 create and send the partial voltage of (Vout/4) to the negative end of the error amplifying and comparing element 122, the error amplifying and comparing element 122 will control the modifying transistor 121 and determine the amount of the voltage released by the modifying transistor 121, and the pump capacitor Cp is charged via the P-type transistor 113. When the first clock CK1 of the charge transistor 111 is at the low level, the second clock CK2 and the third clock CK3 are at the high level, the input end VP charges the pump capacitor Cp having been at the source voltage VDD via the charge transistor 111, and thus, the output voltage Vout is stabilized to be at (l+n) Vref, i.e. Vout=(1+n)×Vref=(1+3)×1.2 V=4.8V.

In summary, the spirit of the present invention is that an input-modifying circuit is installed between the input voltage and the charge-pump circuit and used to control the voltage input to the charge-pump circuit. When the load is greater, the input-modifying circuit releases more voltage; when the load is smaller, the input-modifying circuit releases less voltage. The input-modifying circuit functions like a faucet. When the load is very low, the input-modifying circuit will detect the case and release a smaller amount of voltage. When the load is very high, the input-modifying circuit will detect the case and release a greater amount of voltage. Thereby, the output voltage can be regulated and stabilized without extra adding any LDO and external capacitor to behind the charge-pump circuit.

Those described above are the preferred embodiments to exemplify the present invention. However, it is not intended to limit the scope of the present invention, and any equivalent modification and variation according to the spirit of the present invention is to be also included within the scope of the present invention.

What is claimed is:

1. A charge-pump circuit capable of regulating voltage without any external voltage regulator, which is externally coupled to a pump capacitor and is coupled to a grounded output capacitor at the output end thereof, comprising:
an input-modifying circuit, installed between a voltage-input end and said charge-pump circuit, detecting the variation of the output voltage of said charge-pump circuit, and modifying the voltage input to said charge-pump circuit via a negative feedback mechanism to achieve the stabilization of said output voltage.

2. The charge-pump circuit according to claim 1, wherein said input-modifying circuit further comprises:
a modifying transistor, installed between said voltage-input end and said charge-pump circuit;
a first resistor and a second resistor, interconnected in series from said output end of said charge-pump circuit; and
an error amplifying and comparing element, wherein one input end of said error amplifying and comparing element is coupled to a reference voltage; the other input end is coupled to a junction between said first resistor and said second resistor to obtain the partial voltage of said output voltage at said junction and implement said negative feedback mechanism; and the output end of said error amplifying and comparing element is coupled to the control end of said modifying transistor to control the amount of the voltage released by said modifying transistor.

3. The charge-pump circuit according to claim 2, wherein the resistance ratio of said first resistor and said second resistor is n:1, and n is greater than 1; and thereby, a partial voltage equal to (1/n) said output voltage is generated and output to said error amplifying and comparing element.
